(19) United States
(12) Patent Application Publication
(10) Pub. No.: US 2011/0079906 A1
(43) Pub. Date: Apr. 7, 2011

(54) PRE-PACKAGED STRUCTURE

(76) Inventors: Shih-Wei Tsai, Hsinchu County (TW); Hsiang-Chung Chang, Hsinchu City (TW)

(21) Appl. No.: 12/650,551

(22) Filed: Dec. 31, 2009

(30) Foreign Application Priority Data
Oct. 1, 2009 (TW) 098133374

(51) Int. Cl. H01L 23/49

(52) U.S. Cl. 257/741; 257/784; 257/E23.024

(57) ABSTRACT

A pre-packaged structure includes a substrate with a substrate circuit, a die having a core circuit and disposed on the substrate, a passivation selectively covering the core circuit, a buffer metal layer electrically connected to the core circuit and completely covering the passivation and a copper wire bond electrically connected to the buffer metal layer and the substrate circuit.

### BACKGROUND OF THE INVENTION

1. Field of the Invention

The present invention generally relates to a pre-packaged structure. In particular, the present invention is directed to a pre-packaged structure so that a copper wire can be directly disposed in the pre-packaged structure and right on the core circuit within.

2. Description of the Prior Art

In order to meet the demands of “light, small, short and thin” characteristics for electronic products, the technology of packaging is progressing. During the advancing progress of the technology of packaging, many techniques are developed, such as wire bonding or flip-chip.

Please refer to FIG. 1, which illustrates a conventional technology of packaging. The conventional technology of packaging usually requires a chip substrate 110 to support and to connect at least one die 120 or other packaging element(s) to be packaged to form a chip, which can be further electrically connected to a circuit such as a motherboard (not shown). The die 120 which is supported on the chip substrate 110 usually has the function of heat-dissipation. Generally speaking, the chip substrate 110 may be formed of and laminated by a single or multiple patterned conductive wires 124 and multiple passivations, and the wire bond 150 may further electrically connect the functions of the die 120 to the patterned conductive wires 124 of the chip substrate 110.

As known to persons of ordinary skills in the art, the connecting medium for electrically connecting the die 120 to the chip substrate 110 is usually metal wires of low electric resistance when traditionally the wire bonding is used. The candidates of the metal wires of low electric resistance are usually copper wires and gold wires. Although it is cheaper to choose copper wires instead of gold wires, a much stronger force is however required to fix the copper wires onto the electrical point 115 of the die 120 when copper wires are used to be the connecting medium for electrically connecting the die 120 to the chip substrate 110 because the mechanical strength of pure copper is relatively high. In addition, because such force usually far exceeds the limit which the core circuit 121 within the die 120 can take, cracks 129 and substantial damages to the underlying core circuit 121 are doomed to be caused and as a result, the entire chip is functionally destroyed when the copper wire 150 is directly fixed onto the electrical point 115 right above the core circuit 121. In order to avoid such damages of the core circuit 121, there is a known technique which involves fixing the copper wires 150 onto the periphery circuits 170 around the core circuit 121 to keep the damages from the core circuit 121.

However, if the wires 150 still need to be fixed onto the electrical point 115 right above the core circuit 121, gold wires of much lower mechanical strength must be used to solve the problem. Although the force needed by the gold wires is within the limit of the core circuit 121, gold is however on one hand much more expensive than copper and on the other hand, the electrical resistance of gold is still higher than that of copper, this solution is as a result disadvantageous to the manufactures.

In another aspect, although there may be a layer of metal 115 disposed on the top surface of the conventional die 120, and this metal layer 115 may more or less reduce the stress which the core circuit 121 within the die 120 suffers during the wire bonding process, as described earlier, such metal layer 115 is still substantially insufficient to completely buffer the stress of copper wires which is applied onto the core circuit 121 during the “copper” wire bonding process. Moreover, it is currently impossible to change the properties of the metal layer 115 because any change may result in incompatibility of the current standard semiconductor process between the semiconductor foundries and the packaging houses. Accordingly, a novel pre-packaged structure is therefore still needed in order to solve the aforesaid problems completely.

### SUMMARY OF THE INVENTION

The present invention accordingly proposes a novel pre-packaged structure. In the pre-packaged structure of the present invention, on one hand a buffer metal layer which is thick enough is provided on the top surface of the die to shield the overwhelming stress of the wire bonding for fixing the wires onto the electrically connecting points above the core circuit as well as the potential cracks and substantial damages to the underlying core circuit. On the other hand, the pre-packaged structure of the present invention also allows the copper wires directly electrically connecting the electric points of the core circuit so that one end of the copper wire may be directly disposed right above the core circuit. In such a way, the gold wires, which are expensive and have higher electrical resistance, are no longer needed to take advantage of a lower production cost.

The present invention first proposes a novel pre-packaged structure. The pre-packaged structure of the present invention includes a substrate with a substrate circuit, a die having a core circuit and disposed on the substrate, a passivation selectively covering the core circuit, a buffer metal layer electrically connected to the core circuit and completely covering the passivation and a copper wire bond electrically connected to the buffer metal layer and to the substrate circuit. The buffer metal layer has a thickness of at least 5 μm.

The present invention also proposes another novel pre-packaged structure. The pre-packaged structure of the present invention includes a substrate with a substrate circuit, a die having a core circuit and disposed on the substrate, a passivation selectively covering the core circuit, a buffer metal layer electrically connected to the core circuit and completely covering the passivation and a copper wire bond electrically connected to the buffer metal layer and to the substrate circuit. One end of the copper wire bond is disposed right above the core circuit.

Because the pre-packaged structure of the present invention provides a buffer metal layer which is thick enough on the top surface of the die, there is no needed to concern the overwhelming stress of the wire bonding for fixing the wires onto the electric points above the core circuit and the potential cracks and substantial damages to the underlying core circuit. In another aspect, one end of the copper wire bonds may be disposed right above the core circuit so that the gold wires, which are expensive and have higher electrical resistance, are no longer needed to take the advantage of a lower production cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a conventional technology of packaging.

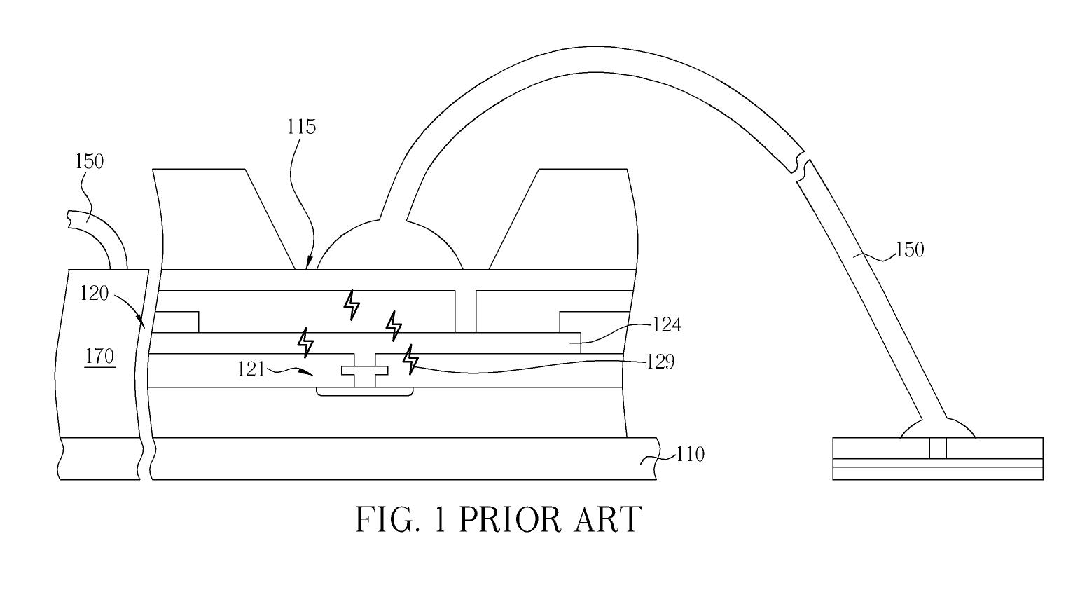

FIG. 2 illustrates an embodiment of the pre-packaged structure of the present invention.

FIG. 3 illustrates another embodiment of the pre-packaged structure of the present invention.

### DETAILED DESCRIPTION

The present invention in one aspect provides a novel pre-packaged structure. In the pre-packaged structure of the present invention, a layer of buffer metal which is thick enough is provided on the top surface of the die to shield the overwhelming stress which is caused by wire bonding for fixing the wire bonds onto the electric points above the core circuit and to avoid the potential cracks and substantial damages to the underlying core circuit. In another aspect, the pre-packaged structure of the present invention also allows the copper wire to directly electrically contact the electric points of the core circuit so that one end of the copper wires is directly disposed right above the core circuit. In such a way, the gold wires, which are expensive and have higher electrical resistance, are no longer needed to take advantage of a lower production cost.

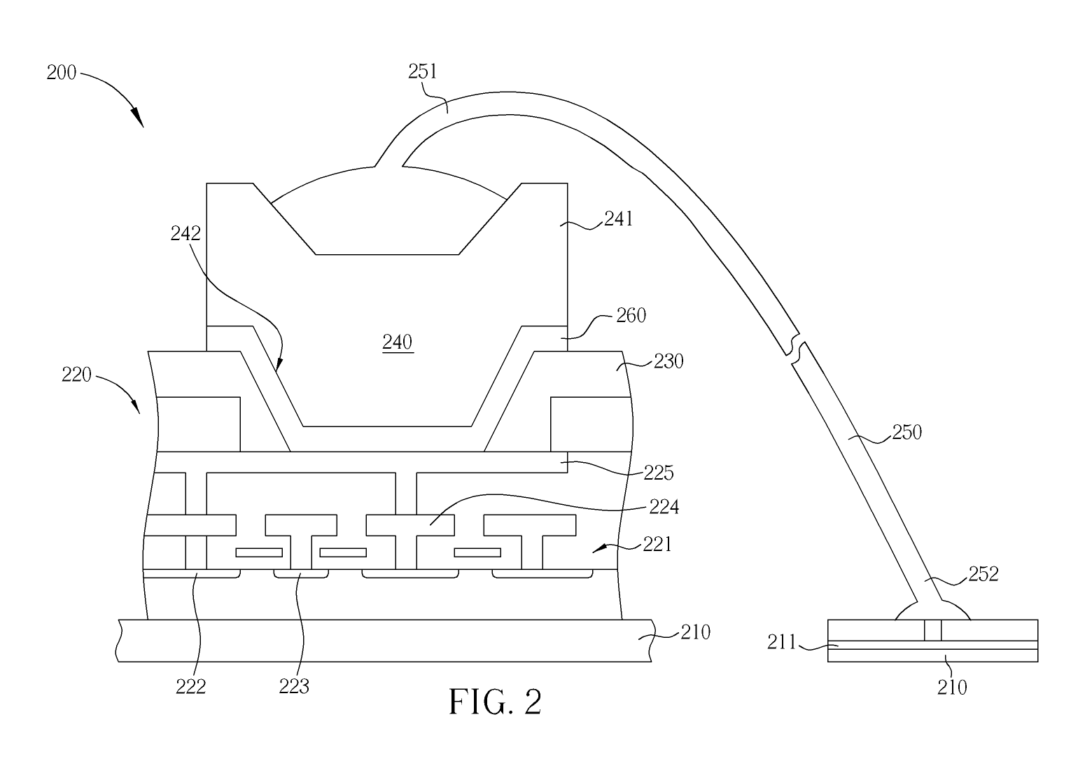

The present invention first provides a novel pre-packaged structure. Please refer to FIG. 2, illustrating an embodiment of the pre-packaged structure of the present invention. The pre-packaged structure 200 of the present invention includes a wafer substrate 210, a die 220, a passivation 230, a buffer metal layer 240 and at least one copper wire bond 250. The wafer substrate 210 is a substrate usually for use in the pre-packaged structure 200. Generally speaking, it may include a wafer substrate circuit 211. Accordingly, it may be electrically connected to other electronic element(s), such as motherboard (not shown) for electrical connection.

The die 220 is disposed on the wafer substrate 210 and includes a core circuit 221. Besides, there may be a peripheral circuit (not shown) which surrounds the core circuit 221. As a result, the peripheral circuit is not disposed right above the core circuit 221. The die 220 may come from a standard semiconductor process, such as from an uncut wafer (not shown) of front-end foundries, or cut from a wafer of back-end assembly houses, so the details will not be discussed here. A core circuit 221 is formed within the die 220. Additionally, the core circuit 221 may include various elements, such as a MOS 222, a power device 233, a metal interconnect 224, etc. Various elements which the core circuit 221 may include are known to persons of ordinary skills in the art so the details will not be discussed here.

In order to protect the core circuit 221 in the die 220, the top surface of the core circuit 221 is usually covered with a layer of passivation 230 so as to keep oxygen, moist or dusts from damaging the core circuit 221 inside the die 220. The passivation 230 may selective cover the core circuit 221, so part of the topmost metal layer 225, also known as a top metal layer 225, of the core circuit 221 is therefore exposed.

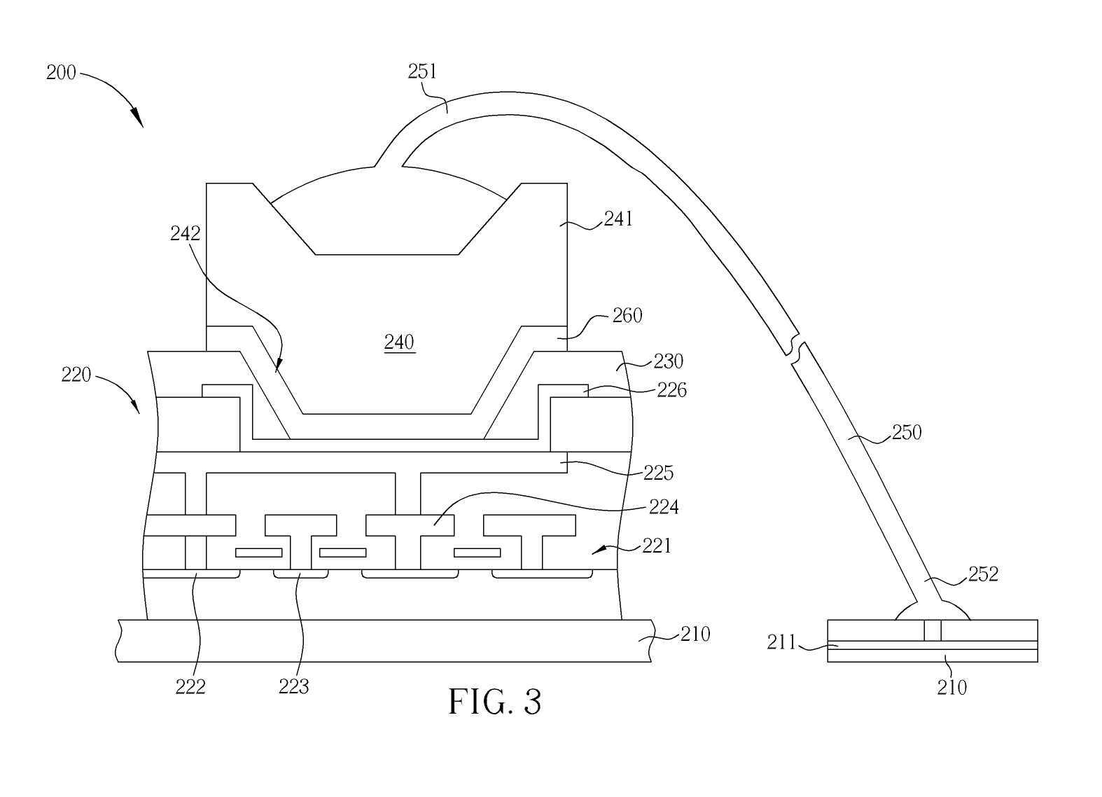

In order to substantially buffer the shock coming from the excess stress of the copper wire bonding, there is a buffer metal layer 240 covering the top metal layer 225 of the core circuit 221 of the present invention. On one hand, the buffer metal layer 240 usually covers the passivation 230. On the other hand, the buffer metal layer 240 is electrically connected to the core circuit 221. For example, the passivation 230 may selectively expose part of the top metal layer 225 of the core circuit 221, thereby the buffer metal layer 240 which contacts the top metal layer 225 forms the electrical connection with the core circuit 221. Optionally, the core circuit 221 may further include a pad 226 so that the buffer metal layer 240 is electrically connected to the pad 226, as shown in FIG. 3.

In order to substantially stand the stress of the copper wire bonding, the buffer metal layer 240 of the present invention should have a sufficient thickness. For example, in a preferred embodiment of the present invention, the thickness of the buffer metal layer 240 should be at least 5 μm, preferably, the thickness of the buffer metal layer 240 may be 8 μm-9 μm. The suitable thickness of the buffer metal layer 240 should be by far larger than the thickness of a metal layer made by a standard semiconductor process. In another preferred embodiment of the present invention, the buffer metal layer 240 may include a RDL 241 (re-distribution layer). Preferably, such buffer metal layer 240 may be obtained by being integrated in the manufacture of the RDL technique.

The material for the buffer metal layer 240 usually includes a metal of low electric resistance, such as Cu, Ag, Au, etc. For example, the buffer metal layer 240 of the present invention substantially consists of copper. Or alternatively, the buffer metal layer 240 includes a copper alloy. For example, Ni and/or Au may be the components for the alloy of the buffer metal layer 240, to be disposed on the surface of the buffer metal layer 240.

Copper wire 250 is used for the electrical connection of the buffer metal layer 240 and the wafer substrate circuit 211, formed by means of the traditional wire-bonding technique to fix two end points 251/252 of the copper wire 250 respectively onto a pad on the surface of the buffer metal layer 240 and of the wafer substrate circuit 211. Optionally, some of the wires may be gold wires. In one embodiment of the present invention, one end 251 of the copper wire 250 is fixed on the core circuit 221, preferably, right on the power device 223. Due to the advantage of having the shortest current path, it is suitable for the power device 223 to directly transport high energy. On the other hand, the buffer metal layer 240 may further include a cavity 242 to accommodate one end 251 of the copper wire 250.

If the adhesion between the buffer metal layer 240 and the passivation 230 needs securing to enhance the interaction between the buffer metal layer 240 and the passivation 230, in one preferred embodiment of the present invention there may be an adhesion-enhancing layer 260 selectively disposed between the buffer metal layer 240 and the passivation 230. The suitable adhesion-enhancing layer 260 is selected in accordance with different buffer metal layer 240 and passivation 230, such as an under bump metallurgy (UBM).

Just because the features of the present invention deal with the force by the copper wires on the core circuit 221 well, especially on the power device 233 during the wire-bonding procedure, the core circuit 221 in the pre-packaged structure 200 of the present invention substantially has no cracks no matter if the core circuit 221 is in an entire wafer (not shown) or not. In such a way, the gold wires, which are expensive and have higher electrical resistance, are no longer needed in the pre-packaged structure 200 of the present invention to take the advantage of a lower production cost.

The pre-packaged structure 200 of the present invention may be further processed to become a conventional packaged structure. For example, the pre-packaged structure 200 of the present invention is hermetically sealed by an epoxy material. Such procedure is known to persons of ordinary skills in the art and the details will not be discussed.

Those skilled in the art will readily observe that numerous modifications and alterations of the device and method may be made while retaining the teachings of the invention.

What is claimed is:

1. A pre-packaged structure, comprising:
a substrate comprising a substrate circuit;
a die having a core circuit and disposed on said substrate;
a passivation selectively covering said core circuit;
a buffer metal layer electrically connected to said core circuit and covering said passivation, wherein said buffer metal layer has a thickness of at last 5 μm; and
a copper wire bond electrically connected to said buffer metal layer and to said substrate circuit.

2. The pre-packaged structure of claim 1, wherein said core circuit comprises a top metal layer so that said buffer metal layer is electrically connected to said top metal layer.

3. The pre-packaged structure of claim 1, wherein said core circuit comprises a pad so that said buffer metal layer is electrically connected to said pad.

4. The pre-packaged structure of claim 1, wherein said core circuit comprises a power device so that one end of said copper wire bond is disposed right above said power device.

5. The pre-packaged structure of claim 1, wherein said passivation selectively exposes said core circuit so that said buffer metal layer is electrically connected to said core circuit.

6. The pre-packaged structure of claim 1, wherein said buffer metal layer substantially consists of copper.

7. The pre-packaged structure of claim 1, wherein said buffer metal layer comprises a copper alloy.

8. The pre-packaged structure of claim 7, wherein said copper alloy comprises at least one of Ni and Au.

9. The pre-packaged structure of claim 1, wherein said buffer metal layer comprises a re-distribution layer (RDL).

10. The pre-packaged structure of claim 1, further comprising:
an adhesion-enhancing layer selectively disposed between said buffer metal layer and said passivation.

11. A pre-packaged structure, comprising:
a substrate comprising a substrate circuit;
a die having a core circuit and disposed on said substrate;
a passivation selectively covering said core circuit;
a buffer metal layer electrically connected to said core circuit and completely covering said passivation; and
a copper wire bond electrically connected to said buffer metal layer and to said substrate circuit, wherein one end of said copper wire bond which is electrically connected to said buffer metal layer is disposed right above said core circuit.

12. The pre-packaged structure of claim 11, wherein said core circuit comprises a top metal layer so that said buffer metal layer is electrically connected to said top metal layer.

13. The pre-packaged structure of claim 11, wherein said core circuit comprises a pad so that said buffer metal layer is electrically connected to said pad.

14. The pre-packaged structure of claim 11, wherein said core circuit comprises a power device.

15. The pre-packaged structure of claim 11, wherein said buffer metal layer comprises a copper alloy.

16. The pre-packaged structure of claim 6, wherein said copper alloy comprises a re-distribution layer (RDL).

17. The pre-packaged structure of claim 11, further comprising:
an adhesion-enhancing layer selectively disposed between said buffer metal layer and said passivation.

18. The pre-packaged structure of claim 11, wherein said core circuit is substantially crack-free.

19. The pre-packaged structure of claim 1, wherein said buffer metal layer comprises a cavity to accommodate said end of said copper wire bond.
